(19) United States
(12) Patent Application Publication
(10) Pub. No.: US 2026/0327061 A1
(43) Pub. Date: Oct. 22, 2026

(54) MEMS microphone

(71) Applicant: AAC ACOUSTIC TECHNOLOGIES (SHENZHEN) CO., LTD., Shenzhen (CN)

(72) Inventors: Yuwei Liu, Singapore (SG); Rui Zhang, Shenzhen (CN)

(21) Appl. No.: 19/720,932

(22) Filed: Jun. 26, 2026

Related U.S. Application Data
(63) Continuation-in-part of application No. 18/399,736, filed on Dec. 29, 2023, now abandoned.
Application No. 18/399,736 is a continuation of application No. PCT/CN2023/086242, filed on Apr. 4, 2023.

(51) Int. Cl. B81B 3/00; H04R 1/08; H04R 19/02

(52) U.S. Cl. CPC B81B 3/0051; H04R 1/08; H04R 19/02; B81B 2201/0257; B81B 2203/0127; B81B 2203/0315; B81B 2203/0353; H04R 2201/003

(57) ABSTRACT

The present disclosure discloses a MEMS microphone including a substrate with a back cavity and a capacitive system arranged on the substrate, the capacitive system includes a back plate and a diaphragm, the diaphragm is located between the substrate and the back plate, the diaphragm is provided with a through hole, the back plate includes a body portion, an extension post extending from the body portion towards the substrate and penetrating the through hole, and a spacer connected to the extension post, the spacer is located between the diaphragm and the substrate, a projection of the spacer along a vibration direction of the diaphragm is at least partially located on the substrate for limiting the movement of the diaphragm toward the substrate to prevent it from colliding with the substrate. Compared with the related art, MEMS microphone disclosed by the present disclosure has a high reliability.

### FIELD OF THE PRESENT DISCLOSURE

The present disclosure relates to acoustic-electro conversion technologies, in particular to a micro-electro-mechanical system (MEMS) microphone.

### DESCRIPTION OF RELATED ART

With rapid developments of the mobile communication technology in recent years, mobile communication devices, such as portable phones, internet-enabled portable phones, personal digital assistants and other devices for communications in dedicated networks, are used more and more. A microphone, especially a MEMS microphone, is one of the most important components used in these devices.

A micro-electro-mechanical system (MEMS) microphone is an electroacoustic transducer produced by micro-mechanical technology, which has a small size, an excellent frequency response characteristic, a low noise, etc. As electronic devices are becoming smaller and thinner, MEMS microphones are increasingly and widely used in these devices.

A MEMS microphone in the related art includes a substrate with a back cavity and a capacitor system arranged on the substrate, the capacitor system includes a back plate and a diaphragm arranged opposite to the back plate. The diaphragm is located on a side of the back plate close to the substrate, and the diaphragm will come into contact with an edge of the substrate during vibration, especially when it is vigorously impacted, so that the strength and reliability of the MEMS microphone will be reduced.

Thus, it is necessary to provide a MEMS microphone to solve the problem.

### SUMMARY OF THE DISCLOSURE

An objective of the present disclosure is to provide a MEMS microphone with a high reliability.

In order to achieve the objective mentioned above, the present disclosure discloses a MEMS microphone including a substrate with a back cavity and a capacitive system arranged on the substrate, the capacitive system includes a back plate and a diaphragm opposite to the back plate, the diaphragm is located between the substrate and the back plate. The diaphragm comprises a vibration portion with a through hole and a fixing portion surrounding the vibration portion, the fixing portion is fixed to the substrate via a supporting member sandwiched between the fixing portion and the substrate. The back plate comprises a body portion, an extension post extending from the body portion towards the substrate and penetrating the through hole, and a spacer connected to the extension post and located between the diaphragm and the substrate, a width of the spacer is greater than a diameter of the through hole, the diaphragm is spaced from the extension post and the spacer, a projection of the spacer along a vibration direction of the diaphragm is at least partially located on the substrate for limiting the movement of the diaphragm toward the substrate to prevent it from colliding with the substrate.

Further, the extension post is a cylinder.

Further, the extension post is integral with the body portion.

Further, the spacer is made of an insulating material.

Further, the extension post and spacer are hollow annular structures.

The present disclosure further discloses a MEMS microphone including a substrate having a back cavity formed by a cavity boundary, a supporting member, a diaphragm, a back plate, an extension post, and a spacer. The supporting member is located on an upper surface of the substrate and keeping a distance from a joint edge connecting the cavity boundary and the upper surface for forming a buffering area. The diaphragm is deformable along a vibration direction and includes a fixing portion carried by the supporting member, a main vibration member having a projection overlapping a projection of the joint edge along the vibration direction, and a suspension having a projection overlapping a projection of the buffering area along the vibration direction for connecting the main vibration portion to the fixing portion. The back plate is located above the diaphragm for forming a capacitive system with the diaphragm. The extension post extends from a bottom surface of the back plate and penetrates the suspension of the diaphragm. The spacer is formed at a distal end of the extension post and is located between a lower surface of the diaphragm and the upper surface of the substrate, for keeping a first distance from a lower surface of the suspension of the diaphragm and a second distance from the upper surface of the substrate, thereby providing a vibration space for the suspension and preventing the suspension from colliding with the substrate.

Further, the suspension includes an inner edge bounding to form a through hole via which the extension post passes, and, at least a part of the inner edge includes a projection along the vibration direction fallen within a projection of the spacer along the vibration direction, such that the spacer serves as a stop for preventing the suspension colliding with the upper surface of the substrate.

Further, a width of the spacer is greater than a diameter of the through hole.

### BRIEF DESCRIPTION OF THE DRAWINGS

Many aspects of the exemplary embodiment can be better understood with reference to the following drawings. The components in the drawings are not necessarily drawn to scale, the emphasis instead being placed upon clearly illustrating the principles of the present disclosure.

FIG. 1 is an isometric view of a MEMS microphone in accordance with an exemplary embodiment of the present disclosure.

FIG. 2 is a schematic view of a partial structure of FIG. 1.

### DETAILED DESCRIPTION OF THE EXEMPLARY EMBODIMENTS

The present disclosure will hereinafter be described in detail with reference to exemplary embodiments. To make the technical problems to be solved, and technical solutions and beneficial effects of the present disclosure more apparent, the present disclosure is described in further detail together with the figure and the embodiment. It should be understood the specific embodiment described hereby is only to explain the disclosure, not intended to limit the disclosure.

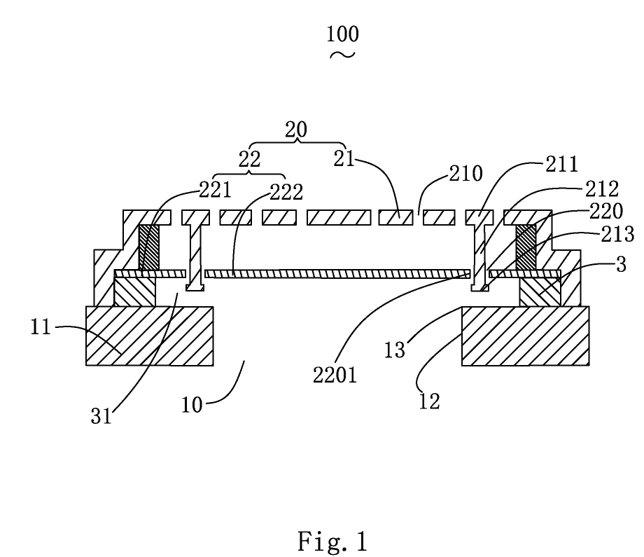

Referring to FIG. 1, this embodiment provides a MEMS microphone 100, including a substrate 11 with a back cavity 10 formed by a cavity boundary 12 and a capacitive system 20 arranged on the substrate 11. The capacitive system 20 includes a back plate 21 and a diaphragm 22 opposite to the back plate 21, the diaphragm 22 is located on a side of the back plate 21 close to the substrate 11. When the sound pressure acts on the diaphragm 22, there is a pressure difference between the two sides of the diaphragm 22 facing the back plate 21 and the diaphragm 22 away from the back plate 21, so that the diaphragm 22 moves closer to the back plate 21 or away from the back plate 21, thereby causing a change in capacitance between the diaphragm 22 and the back plate 21 which will realize the conversion of the sound signal to the electrical signal.

The diaphragm 22 includes a vibration portion 222 with a through hole 220 and a fixing portion 221 surrounding the vibration portion 222, the fixing portion 221 is fixed to the substrate via a supporting member 3 sandwiched between the fixing portion 221 and the substrate 11, the through hole 220 could adjust the damping of the diaphragm 22. The supporting member 3 is located on an upper surface of the substrate 11 and keeping a distance from a joint edge 13 connecting the cavity boundary 12 and the upper surface for forming a buffering area 31. The back plate 21 includes a body portion 211, an extension posts 212 extending from the body portion 211 towards the substrate 11 and penetrating the through hole 220, and a spacer 231 connected to the extension post 212. The body portion 211 is provided with a plurality of back plate holes 210. One end of the extension post 212 is connected to the body portion 211 of the back plate 21, the other end of the extension post 212 is connected to the spacer 231. In addition, the spacer 213 is located between the diaphragm 22 and the substrate 11.

A projection of the spacer 213 along a vibration direction of the diaphragm 22 is at least partially located on the substrate 11. When the diaphragm 22 is operating under acoustic pressure, the diaphragm 22 moves upward, and this structure of the back plate 21 does not affect the degree of freedom of the diaphragm 22, so that there is no loss of the sensitivity of the diaphragm 22; and in the event that the MEMS microphone 100 is dropped or vigorously impacted, the spacer 213 of the back plate 21 protects the diaphragm 22 so that the diaphragm 22 does not come into direct contact with the edges of the substrate 11, which strengthens the diaphragm 22 and alleviates any damage to the diaphragm 22 when it comes into contact with the substrate 11.

A width of the spacer 213 is greater than a width of the extension post 212 and greater than a diameter of the through hole 220, which can make the diaphragm 22 contact with the spacer 213 or the spacer 213 contact with the substrate 11 when the amplitude of the diaphragm 22 is too large, and play a role of protecting the diaphragm 22.

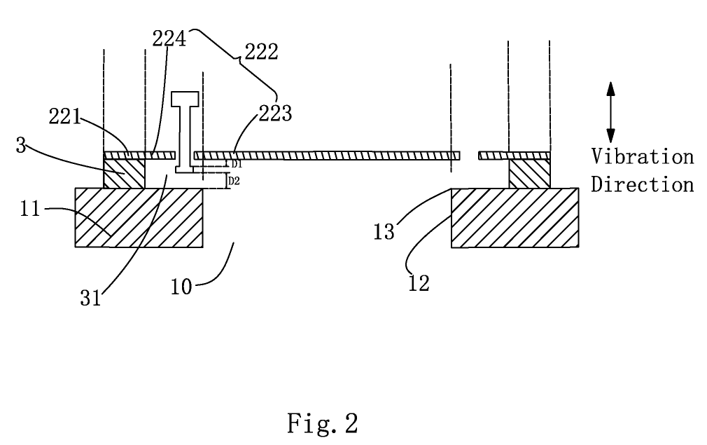

Referring to FIG. 2, together with FIG. 1, the vibration portion 222 of the diaphragm 22 may further include a main vibration member 223 having a projection overlapping a projection of the joint edge 13 along the vibration direction, and a suspension 224 having a projection overlapping a projection of the buffering area 31 along the vibration direction for connecting the main vibration portion 223 to the fixing portion 221. The through hole 220 is formed in the suspension 224. The spacer 213 is formed at a distal end of the extension post 212 and locating between a lower surface of the diaphragm 22 and the upper surface of the substrate 11, for keeping a first distance D1 from a lower surface of the suspension 224 of the diaphragm and a second distance D2 from the upper surface of the substrate 11, thereby providing a vibration space for the suspension 224 and preventing the suspension 224 from colliding with the substrate 11. In addition, the suspension 224 includes an inner edge 2201 bounding to form the through hole 220 via which the extension post 212 passes, and, at least a part of the inner edge 2201 includes a projection along the vibration direction fallen within a projection of the spacer 213 along the vibration direction, such that the spacer 213 serves as a stop for preventing the suspension 224 colliding with the upper surface of the substrate 11.

The extension post 212 may be an integral structure with the body portion 211, i.e., the nitride back plate is formed deposition directly, and the spacer 213 is made of an insulating material. Alternatively, in this embodiment, the extension post 212 and the spacer 213 are hollow annular structures, and in other embodiments, the extension post and the spacer may be a number of separate structures.

Compared with the related art, by providing a spacer 213 connected to the body portion 211 of the back plate 21 between the diaphragm 22 and the substrate 11, the direct contact between the diaphragm 22 and the edge of the substrate 11 is avoided, the strength of the diaphragm 22 is strengthened, and the effect of reliability of the product can be improved.

It is to be understood, however, that even though numerous characteristics and advantages of the present exemplary embodiment have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms where the appended claims are expressed.

What is claimed is:

1. A MEMS microphone, comprising:
a substrate with a back cavity; and
a capacitive system arranged on the substrate, comprising a back plate and a diaphragm opposite to the back plate, the diaphragm located between the substrate and the back plate; wherein
the diaphragm comprises a vibration portion with a through hole and a fixing portion surrounding the vibration portion, the fixing portion is fixed to the substrate via a supporting member sandwiched between the fixing portion and the substrate,
the back plate comprises a body portion, an extension post extending from the body portion towards the substrate and penetrating the through hole, and a spacer connected to the extension post and located between the diaphragm and the substrate, a width of the spacer is greater than a diameter of the through hole, the diaphragm is spaced from the extension post and the spacer, a projection of the spacer along a vibration direction of the diaphragm is at least partially located on the substrate for limiting the movement of the diaphragm toward the substrate to prevent it from colliding with the substrate.

2. The MEMS microphone as described in claim 1, wherein the extension post is a cylinder.

3. The MEMS microphone as described in claim 1, wherein the extension post is integral with the body portion.

4. The MEMS microphone as described in claim 1, wherein the spacer is made of an insulating material.

5. The MEMS microphone as described in claim 1, wherein the extension post and spacer are hollow annular structures.

6. A MEMS microphone including:
a substrate having a back cavity formed by a cavity boundary;
a supporting member located on an upper surface of the substrate and keeping a distance from a joint edge connecting the cavity boundary and the upper surface for forming a buffering area;
a diaphragm, being deformable along a vibration direction, including a fixing portion carried by the supporting member, a main vibration member having a projection overlapping a projection of the joint edge along the vibration direction, and a suspension having a projection overlapping a projection of the buffering area along the vibration direction for connecting the main vibration portion to the fixing portion;
a back plate located above the diaphragm for forming a capacitive system with the diaphragm;
an extension post extending from a bottom surface of the back plate and penetrating the suspension of the diaphragm;
a spacer formed at a distal end of the extension post and located between a lower surface of the diaphragm and the upper surface of the substrate, for keeping a first distance from a lower surface of the suspension of the diaphragm and a second distance from the upper surface of the substrate, thereby providing a vibration space for the suspension and preventing the suspension from colliding with the substrate.

7. The MEMS microphone as described in claim 6, wherein the suspension includes an inner edge bounding to form a through hole via which the extension post passes, and, at least a part of the inner edge includes a projection along the vibration direction fallen within a projection of the spacer along the vibration direction, such that the spacer serves as a stop for preventing the suspension colliding with the upper surface of the substrate.

8. The MEMS microphone as described in claim 7, wherein a width of the spacer is greater than a diameter of the through hole.
